(19) United States
(12) Patent Application Publication
(10) Pub. No.: US 2024/0338502 A1
(43) Pub. Date: Oct. 10, 2024

(54) BROADBAND CAMOUFLAGE PATTERN FORMING DEVICE AND OPERATION METHOD THEREOF

(71) Applicant: ELECTRONICS AND TELECOMMUNICATIONS RESEARCH INSTITUTE, Daejeon (KR)

(72) Inventors: Tae-Youb KIM, Daejeon (KR); Juhyun PARK, Daejeon (KR); Chil Seong AH, Daejeon (KR); Ji-Young OH, Daejeon (KR); Doo-Hee CHO, Daejeon (KR)

(73) Assignee: ELECTRONICS AND TELECOMMUNICATIONS RESEARCH INSTITUTE, Daejeon (KR)

(21) Appl. No.: 18/588,469

(22) Filed: Feb. 27, 2024

(30) Foreign Application Priority Data
Apr. 4, 2023 (KR) 10-2023-0044280
Oct. 5, 2023 (KR) 10-2023-0132634

(51) Int. Cl. G06F 30/27; F41H 3/00; H04N 23/21; H04N 23/23

(52) U.S. Cl. CPC G06F 30/27; F41H 3/00; H04N 23/21; H04N 23/23

(57) ABSTRACT

Disclosed is a camouflage pattern forming device, which includes a communication unit that receives first data including a location of an observer from an external device, an information collection unit that collects second data including images for each of a plurality of wavelength bands in external environment, a pattern forming unit that forms pattern data of the plurality of wavelength bands by performing machine learning based on the first data, the second data, and third data including camouflage pattern data for each environment, and a display unit that receives the pattern data from the pattern forming unit to form and display a camouflage patterns of the plurality of wavelength bands, and the display unit includes a display device and a heat generator capable of adjusting a heat emissivity.

### CROSS-REFERENCE TO RELATED APPLICATIONS

This application claims priority under 35 U.S.C. § 119 to Korean Patent Application Nos. 10-2023-0044280 filed on Apr. 4, 2023, and 10-2023-0132634 filed on Oct. 5, 2023, respectively, in the Korean Intellectual Property Office, the disclosures of which are incorporated by reference herein in their entireties.

### BACKGROUND

Embodiments of the present disclosure described herein relate to forming of a camouflage pattern, and more particularly, relate to a broadband camouflage pattern forming device and an operation method thereof.

With the development of modern science and technology, the effectiveness of military operations may be maximized by analyzing the enemy's weapon systems or tactics through military technology and strengthening the country's military technologies. In particular, among military technologies, military camouflage technology may play a significant role in increasing the military's survivability. Military camouflage may maintain the secrecy of military operations and may reduce the threat of enemy forces. Military camouflage includes stealth technology, fake satellite technology, electronic warfare technology, and digital camouflage technology.

Conventional camouflage technology creates digital patterns based on five digital colors. The conventional camouflage technology may prevent objects from being visually detected by dispersing the silhouette of an object and distorting its shadow based on regular patterns. However, with the development of detection equipment, it becomes increasingly difficult to avoid detection, and camouflage in multiple wavelength bands other than visible light is required depending on situations.

### SUMMARY

Embodiments of the present disclosure provide a device that forms a camouflage pattern with respect to a plurality of wavelength regions, unlike a conventional device that forms a camouflage pattern with respect to a single wavelength region.

According to an embodiment of the present disclosure, a camouflage pattern forming device includes a communication unit that receives first data including a location of an observer from an external device, an information collection unit that collects second data including images for each of a plurality of wavelength bands in external environment, a pattern forming unit that forms pattern data of the plurality of wavelength bands by performing machine learning based on the first data, the second data, and third data including camouflage pattern data for each environment, and a display unit that receives the pattern data from the pattern forming unit to form and display a camouflage patterns of the plurality of wavelength bands, and the display unit includes a display device and a heat generator capable of adjusting a heat emissivity.

According to an embodiment, the number of the plurality of wavelength bands may be determined depending on a surrounding environment of the camouflage pattern forming device and a wavelength band detectable by the observer, and the surrounding environment may include a time of the forming and displaying the camouflage pattern.

According to an embodiment, the first data may further include location information and surrounding environment information of pattern forming device, and location information detection equipment of the observer.

According to an embodiment, the second data may be collected by an observation equipment, and the observation equipment may include a camera, a thermal imaging camera, and a heat detector.

According to an embodiment, the pattern forming unit may further form a first simulation pattern by performing the machine learning based on the first data, the second data, and the third data through the machine learning.

According to an embodiment, the plurality of wavelength bands may include a visible light band, a near-infrared band, and a thermal infrared band, and the time for forming the camouflage pattern may include day and night, when it is the day, the camouflage pattern in the visible light band, the near-infrared band, and the thermal infrared band may be formed and displayed, and when it is the night, the camouflage pattern in the near-infrared band, and the thermal infrared band may be formed and displayed.

According to an embodiment, the pattern forming unit may verify a camouflage performance by comparing the camouflage performance of the first simulation pattern with a threshold, and may determine whether to form the pattern data.

According to an embodiment, the pattern forming unit, when the camouflage performance of the simulation pattern exceeds the threshold, may form the pattern data, when the camouflage performance of the simulation pattern does not exceed the threshold, may form a second simulation pattern by performing the machine learning based on the comparison and analysis of the first data, the second data, and the third data through the machine learning, and may verify the camouflage performance of the second simulation pattern.

According to an embodiment of the present disclosure, a method of forming a camouflage pattern of a camouflage pattern forming device includes receiving first data including a location of an observer from an external device, forming a simulation pattern of a plurality of wavelength bands by performing machine learning based on the first data, second data including images of the plurality of wavelength bands of a surrounding environment of the camouflage pattern forming device, and third data including camouflage pattern data for each environment, verifying a camouflage performance of the simulation pattern, and forming and displaying the camouflage pattern corresponding to each of the plurality of wavelength bands based on the simulation pattern for which the camouflage performance is verified.

According to an embodiment, the number of the plurality of wavelength bands may be determined depending on a surrounding environment of the camouflage pattern forming device and a wavelength band detectable by the observer, and the surrounding environment may include a time of the forming and displaying the camouflage pattern.

According to an embodiment, the first data may further include location information and surrounding environment information of pattern forming device, and location information detection equipment of the observer.

According to an embodiment, the second data may be collected by an observation equipment, and the observation equipment may include a camera, a thermal imaging camera, and a heat detector.

According to an embodiment, the simulation pattern of the plurality of wavelength bands may be formed by comparing and analyzing the first data, the second data, and the third data based on an artificial intelligence.

According to an embodiment, the verification of the camouflage performance may be performed by comparing the camouflage performance of the simulation pattern threshold based on an artificial intelligence.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a camouflage pattern forming device according to an embodiment of the present disclosure.

FIG. 2 is a block diagram illustrating in detail an information collection unit of a camouflage pattern forming device of FIG. 1, according to an embodiment of the present disclosure.

FIG. 3 is a block diagram illustrating in detail a pattern forming unit of a camouflage pattern forming device of FIG. 1, according to an embodiment of the present disclosure.

FIG. 4 is a block diagram illustrating a pattern forming unit of FIG. 1, according to an embodiment of the present disclosure.

FIG. 5 is a flowchart illustrating a method of forming a camouflage pattern in a camouflage pattern forming device of FIG. 1, according to an embodiment of the present disclosure.

### DETAILED DESCRIPTION

Hereinafter, embodiments of the present disclosure will be described in detail and clearly to such an extent that an ordinary one in the art easily implements the present disclosure.

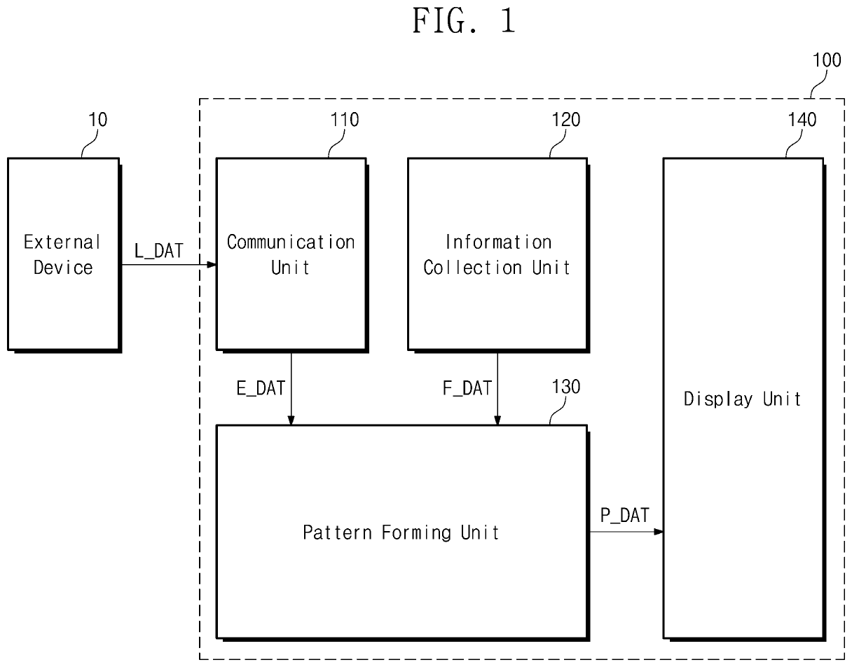

FIG. 1 is a block diagram illustrating a camouflage pattern forming device 100 according to an embodiment of the present disclosure. Referring to FIG. 1, the camouflage pattern forming device 100 may include a communication unit 110, an information collection unit 120, a pattern forming unit 130, and a display unit 140. Hereinafter, various blocks are illustrated as performing operations and functions, but it should be understood that the present disclosure is not limited thereto, and functions performed by a specific block may be performed by other blocks.

The camouflage pattern forming device 100 may generate camouflage patterns in a plurality of wavelength bands. For example, the camouflage pattern forming device 100 may form a camouflage pattern in a visible light band, far-infrared band, and thermal infrared band. In an embodiment, the camouflage pattern forming device 100 may be included on the surface of various military equipment. For example, the camouflage pattern forming device 100 may be included on the surface of various military equipment, such as military aircraft, military ships, military vehicles, artillery, armored vehicles, microphones, cameras, surveillance equipment, or military uniforms.

In an embodiment, the camouflage pattern forming device 100 may determine at least one wavelength band to be displayed among a plurality of wavelength bands according to the surrounding environment, and may generate and display camouflage patterns corresponding to the determined wavelength bands. For example, when the camouflage pattern forming device 100 is located in a forest and the surrounding environment is daytime, the camouflage pattern forming device 100 may form a camouflage pattern in the visible light band having brightness and saturation corresponding to the surrounding environment, such as the color of conifers and the color of tree trunks, and may form a camouflage pattern in the near-infrared or thermal infrared band that corresponds to the temperature and thermal emissivity of the surrounding environment. For another example, when the surrounding environment is night, the camouflage pattern forming device 100 may not form a camouflage pattern in the visible light band, but may form and display a camouflage pattern in the infrared band corresponding to the temperature and thermal emissivity of the surrounding environment.

The above-described content is illustrative and the scope of the present disclosure is not limited thereto. The camouflage pattern forming device 100 may select suitable wavelength bands that may maximize camouflage performance among a plurality of wavelength bands at times other than day and night, and may form and display camouflage patterns corresponding to them. Suitable wavelength bands may be selected based on the range and number of wavelength bands that may be detected by other devices, and the range and number of wavelength bands that may be detected by other devices at the time of forming the camouflage pattern.

An external device 10 may provide various information L_DAT to the camouflage pattern forming device 100. For example, the external device 10 may provide various information L_DAT, such as location information or performance of the observer or the observer's detection equipment, location information of the camouflage pattern forming device 100, or information on the surrounding environment of the camouflage pattern forming device 100 to the camouflage pattern forming device 100. In an embodiment, the external device 10 may be a variety of observation equipment. For example, the external device 10 may be an unmanned aerial vehicle, drone, or satellite. The external device 10 may provide the various information L_DAT through the communication unit 110 of the camouflage pattern forming device 100.

The communication unit 110 may receive the various information L_DAT from the external device 10. In an embodiment, the communication unit 110 may receive the various information L_DAT from the external device 10 through wireless communication. For example, the communication unit 110 may receive the various information L_DAT from the external device 10 through satellite communication, mobile communication, or military communication.

The communication unit 110 may transmit some or all of the received various information L_DAT to the pattern forming unit 130 as environmental data E_DAT. For example, the communication unit 110 may transmit the environmental data E_DAT including information on the surrounding environment of the camouflage pattern forming device 100 to the pattern forming unit 130.

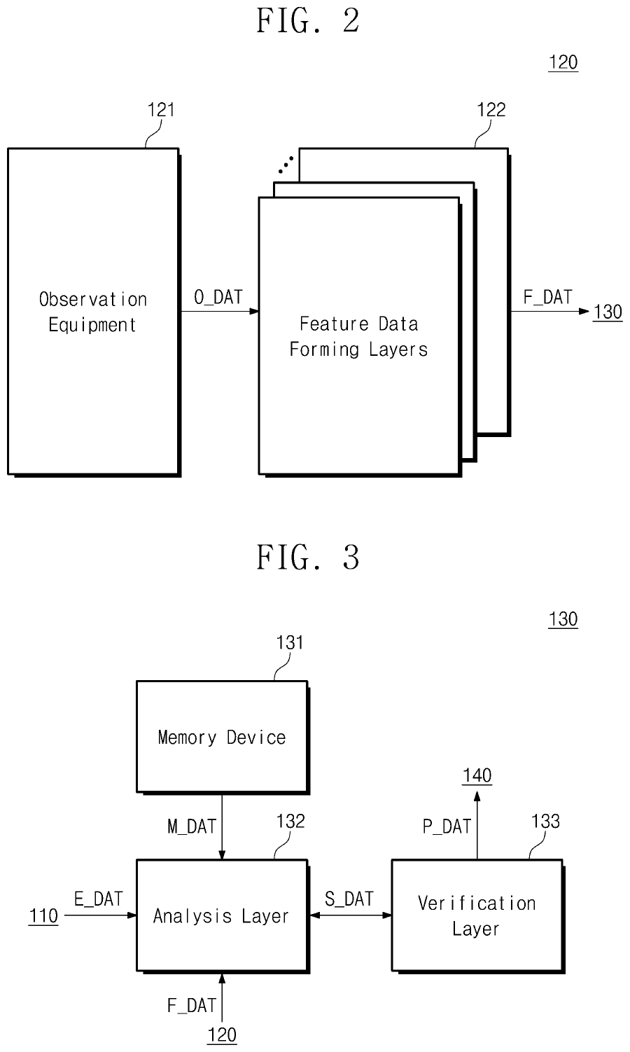

The information collection unit 120 may form feature data F_DAT for each of a plurality of wavelength bands. The feature data F_DAT may be data that serves as the basis for the pattern forming unit 130 to generate a camouflage pattern. In an embodiment, the information collection unit 120 may generate the feature data F_DAT corresponding to all or some of the plurality of wavelength bands, depending on the environment of the camouflage pattern forming device 100. For example, the information collection unit 120 may form the feature data F_DAT in the visible light band, near-infrared band, or thermal infrared band. The information collection unit 120 may provide each feature data F_DAT to the pattern forming unit 130 for each of the plurality of formed wavelength bands. The information collection unit 120 will be described in more detail with reference to FIG. 2.

The pattern forming unit 130 may form the pattern data P_DAT based on the feature data F_DAT received from the information collection unit 120. In an embodiment, the pattern forming unit 130 may form each pattern data P_DAT for each of a plurality of wavelength bands. For example, the pattern forming unit 130 may form the pattern data P_DAT in the visible light band, near-infrared band, or thermal infrared band. The pattern forming unit 130 may transmit the formed pattern data P_DAT to the display unit 140. The pattern forming unit 130 will be described in more detail with reference to FIG. 3.

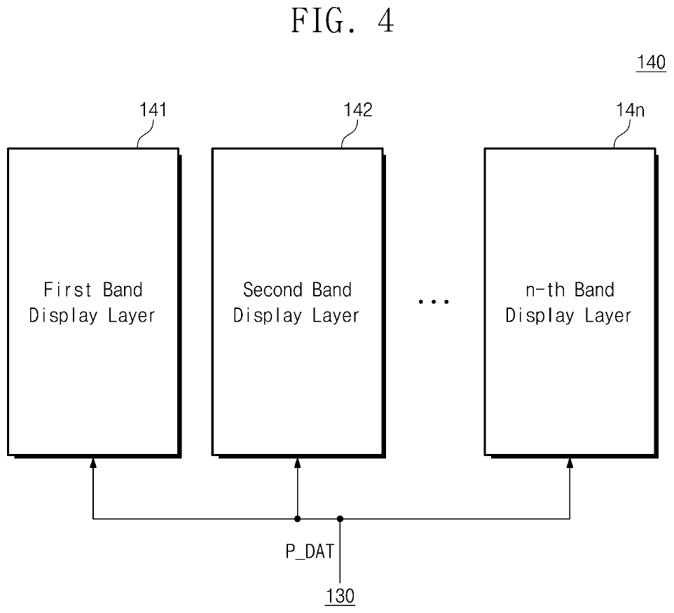

The display unit 140 may form the camouflage pattern based on the pattern data P_DAT received from the pattern forming unit 130 and may display the camouflage pattern in each cell of the camouflage pattern forming device 100. In an embodiment, the display unit 140 may form and display camouflage patterns in each of the plurality of wavelength bands. For example, the display unit 140 may form and display a visible light camouflage pattern, a near-infrared camouflage pattern, or a thermal infrared camouflage pattern. In an embodiment, the display unit 140 may select at least one wavelength band to form a pattern among a plurality of wavelength bands according to the surrounding environment of the camouflage pattern forming device 100, and may form and display a corresponding camouflage pattern. The display unit 140 will be described in more detail with reference to FIG. 4.

FIG. 2 is a block diagram illustrating in detail the information collection unit 120 of the camouflage pattern forming device 100 of FIG. 1, according to an embodiment of the present disclosure. Referring to FIG. 2, the information collection unit 120 may include observation equipment 121 and feature data forming layers 122. Through FIG. 2, the operation process of the information collection unit 120 will be described in detail.

The observation equipment 121 may capture information about the surrounding environment of the camouflage pattern forming device 100. In an embodiment, the observation equipment 121 may include sub-configurations that capture surrounding environment information in the plurality of wavelength bands. For example, the observation equipment 121 may include a camera that captures environmental information in the visible light band, a near-infrared camera that captures environmental information in the near-infrared band, thermal imaging surveillance equipment, or a thermal imaging camera.

The observation equipment 121 may form observation data O_DAT based on the observation results. In an embodiment, the observation equipment 121 may form the observation data O_DAT for each of the plurality of wavelength bands based on observation results for each of the plurality of wavelength bands. For example, the observation equipment 121 may form the observation data O_DAT for the visible light band, near-infrared band, or thermal infrared band based on the observation results. The observation equipment 121 may transmit the observation data O_DAT to the feature data forming layers 122.

The feature data forming layers 122 may form the feature data F_DAT based on observation data O_DAT received from the observation equipment 121. In an embodiment, the feature data forming layers 122 may form the feature data F_DAT for each of a plurality of wavelength regions. For example, the feature data forming layers 122 may form visible light feature data F_DAT, near-infrared feature data F_DAT, thermal infrared feature data F_DAT, etc.

In an embodiment, the number of layers of the feature data forming layers 122 may be determined based on the number of wavelength bands in which the feature data F_DAT is formed. For example, the feature data forming layers 122 may include three layers when the feature data F_DAT in the visible light, the far-infrared band, and the near-infrared band are formed.

In an embodiment, the number of wavelength bands in which the feature data F_DAT is formed may be determined based on the performance of the observer or the observer's detection equipment received from the external device 10. For example, when the observer's detection equipment has detection capabilities of the visible light band and the near-infrared band, the number of wavelength bands may be two, including the visible light band and the near-infrared band. The feature data forming layers 122 may provide the formed feature data F_DAT to the pattern forming unit 130.

FIG. 3 is a diagram illustrating the pattern forming unit 130 of FIG. 1 in detail, according to an embodiment of the present disclosure. Referring to FIG. 3, the pattern forming unit 130 may include a memory device 131, an analysis layer 132, and a verification layer 133. Through FIG. 3, the pattern forming unit 130 will be described in detail.

The memory device 131 may store camouflage pattern data M_DAT. In an embodiment, the memory device 131 may store the camouflage pattern data M_DAT grouped by environmental types. For example, the memory device 131 may store the camouflage pattern data M_DAT grouped by the environmental types, such as mountains, swamps, broad-leaved forests, coniferous forests, deserts, or polar regions. The memory device 131 may provide the camouflage pattern data M_DAT to the analysis layer 132.

The analysis layer 132 may compare and analyze the feature data F_DAT and the camouflage pattern data M_DAT. In an embodiment, the analysis layer 132 may utilize artificial intelligence AI to compare and analyze the feature data F_DAT and the camouflage pattern data M_DAT.

The analysis layer 132 may receive the camouflage pattern data M_DAT that matches the surrounding environment of the camouflage pattern forming device 100 from the memory device 131. In an embodiment, the analysis layer 132 may determine the camouflage pattern data M_DAT to be received based on the surrounding environment information of the camouflage pattern forming device 100 in the environmental data E_DAT received from the communication unit 110. For example, when the environment surrounding of the camouflage pattern forming device 100 is a coniferous forest, the analysis layer 132 may receive coniferous forest camouflage pattern data M_DAT from the memory device 131.

The analysis layer 132 may form a simulation pattern S_DAT based on the comparison and analysis results of feature data F_DAT and the camouflage pattern data M_DAT. In an embodiment, the analysis layer 132 may utilize artificial intelligence to form the simulation pattern S_DAT for a plurality of wavelength bands. For example, the analysis layer 132 may utilize artificial intelligence to form the simulation pattern S_DAT in the visible band, the simulation pattern S_DAT in the near-infrared band, or the simulation pattern S_DAT in the thermal infrared band.

In an embodiment, the analysis layer 132 may determine data included in the simulation pattern S_DAT based on characteristics of wavelength bands. For example, the analysis layer 132 may form the simulation pattern S_DAT including data such as color, brightness, and saturation with respect to the visible light band. As another example, the analysis layer 132 may form the simulation pattern S_DAT including near-infrared image data and thermal emissivity data with respect to the infrared band. The analysis layer 132 may provide the formed simulation pattern S_DAT to the verification layer 133.

The verification layer 133 may verify the camouflage performance of the simulation pattern S_DAT based on artificial intelligence. In an embodiment, the verification layer 133 may verify the camouflage performance of the simulation pattern S_DAT using a threshold. For example, the verification layer 133 may verify the camouflage performance of the simulation pattern S_DAT based on a threshold associated with similarity between the observation data of the observation equipment 121 of FIG. 2 and the simulation pattern S_DAT.

In an embodiment, the verification layer 133 may verify the camouflage performance of each simulation pattern S_DAT for each wavelength band. For example, the verification layer 133 may verify whether the simulation pattern S_DAT in the visible light band and the simulation pattern S_DAT in the infrared band each have camouflage performance that exceeds the threshold of the wavelength band.

In an embodiment, when the simulation pattern S_DAT does not have the camouflage performance higher than the threshold in at least one wavelength band, the verification layer 133 may cause the analysis layer 132 to form the new simulation pattern S_DAT. The verification layer 133 may repeat the above-described process until the simulation pattern S_DAT has the camouflage performance exceeding the threshold in all wavelength bands.

When the simulation pattern S_DAT has the camouflage performance higher than the threshold in all wavelength bands, the verification layer 133 may form the pattern data P_DAT. In an embodiment, the verification layer 133 may form the pattern data P_DAT for each of a plurality of wavelength bands. For example, the verification layer 133 may form the visible light band pattern data P_DAT, the infrared band pattern data P_DAT, etc. The verification layer 133 may transmit the formed pattern data P_DAT to the display unit 140.

FIG. 4 is a block diagram illustrating in detail the display unit 140 of the camouflage pattern forming device 100 of FIG. 1, according to an embodiment of the present disclosure. Referring to FIG. 4, the display unit 140 may include display layers 141 to 14n of a plurality of wavelength bands. Through FIG. 4, a process by which the camouflage pattern forming device 100 displays a camouflage pattern is described.

The display layers 141 to 14n of the plurality of wavelength bands may form a camouflage pattern in cells on the surface of the camouflage pattern forming device 100 based on the pattern data P_DAT received from the pattern forming unit 130 for each wavelength band. For example, the first band display layer 141 may form a camouflage pattern in the visible light band, the second band display layer 142 may form a camouflage pattern in the near-infrared band, and the third band display layer 143 may form a camouflage pattern in the thermal infrared band.

In an embodiment, the plurality of wavelength band display layers 141 to 14n may include a configuration that may form a pattern corresponding to each wavelength band. For example, the first band display layer 141 displaying a camouflage pattern in the visible light band may include a display device (e.g., a flat panel display device, a curved display device, etc.). As another example, the second band display layer 142 displaying a camouflage pattern in the infrared band may include a heat generator with adjustable thermal emissivity.

Although it is described that display layers 141 to 14n of the plurality of wavelength bands each form a camouflage pattern to match the wavelength band, the scope of the present disclosure is not limited thereto. It should be understood that one band display layer (one of 141 to 14n) is capable of forming a camouflage pattern of a plurality of wavelength bands, and should be understood to be included in the scope of the present disclosure.

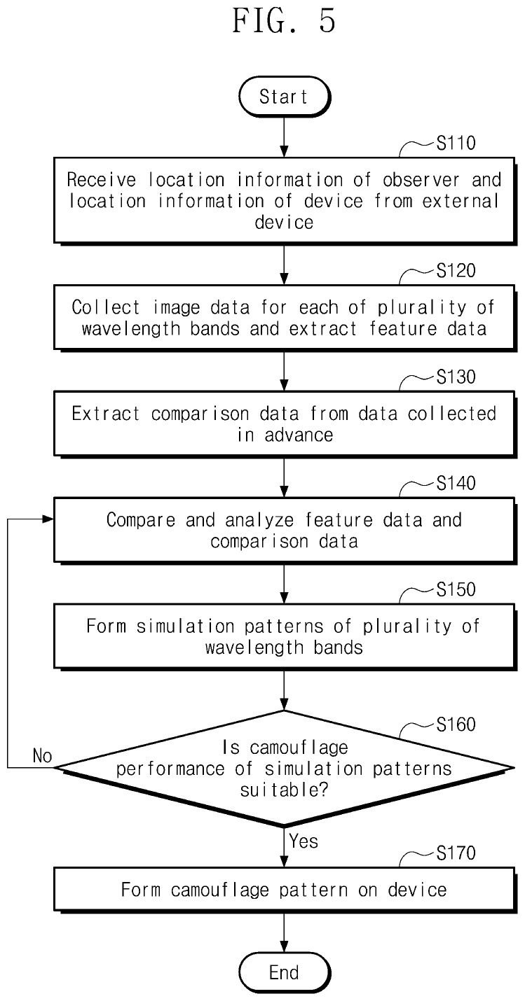

FIG. 5 is a flowchart illustrating a method of operating the camouflage pattern forming device 100 of FIG. 1, according to an embodiment of the present disclosure. Through FIGS. 1 and 5, a method for forming a wideband camouflage pattern according to an embodiment of the present disclosure will be described.

In operation S110, the camouflage pattern forming device 100 may receive location information of the observer and location information of the camouflage pattern forming device 100 from the external device 10. In an embodiment, the camouflage pattern forming device 100 may receive location information of an enemy unmanned aerial vehicle, information on the surrounding environment of the camouflage pattern forming device 100, etc. from the external device 10 through the communication unit 110.

In operation S120, the camouflage pattern forming device 100 may collect image data for each of a plurality of wavelength bands and may extract feature data. In an embodiment, referring to FIG. 2 together, the camouflage pattern forming device 100 may collect image data for each of a plurality of wavelength bands through the observation equipment 121. For example, the camouflage pattern forming device 100 may collect image data in the visible light, near-infrared, and thermal infrared bands through the observation equipment 121. In an embodiment, the camouflage pattern forming device 100 may extract the feature data from collected image data through the feature data forming layers 122 of FIG. 2.

In operation S130, the camouflage pattern forming device 100 may extract comparison data from data collected in advance. In an embodiment, the data collected in advance may be image data for each of environmental information. For example, the data collected in advance may include camouflage pattern data according to the surrounding environment of the camouflage pattern forming device 100.

In an embodiment, the comparison data may include camouflage pattern data for each of a plurality of wavelength bands. For example, when the surrounding environment is a coniferous forest, the comparison data may include camouflage pattern data in the visible light band, camouflage pattern data in the near-infrared band, or camouflage pattern data in the thermal infrared band with respect to the coniferous forest.

In operation S140, the camouflage pattern forming device 100 may compare and analyze the feature data and the comparison data. In an embodiment, the camouflage pattern forming device 100 may compare and analyze the feature data and the environmental comparison data based on artificial intelligence or machine learning. For example, the camouflage pattern forming device 100 may compare and analyze the feature data and the camouflage pattern data of the surrounding environment in the comparison layer 132 of FIG. 3 based on artificial intelligence and machine learning.

In operation S150, the camouflage pattern forming device 100 may form simulation patterns of a plurality of wavelength bands based on comparison and analysis results. In an embodiment, the camouflage pattern forming device 100 may form simulation patterns of a plurality of wavelength bands through the analysis layer 132 of FIG. 3. For example, the camouflage pattern forming device 100 may form a visible light band simulation pattern, a near-infrared band simulation pattern, etc. through the analysis layer 132.

In operation S160, the camouflage pattern forming device 100 may verify whether the camouflage performance of the simulation patterns of the plurality of wavelength bands is suitable. In an embodiment, the camouflage pattern forming device 100 may verify whether the camouflage performance is suitable for each wavelength band of simulation patterns in a plurality of wavelength bands through the verification layer 133 of FIG. 3. For example, the camouflage pattern forming device 100 may verify whether the camouflage performance of the simulation pattern in the visible light band is suitable, whether the camouflage performance of the simulation pattern in the near-infrared band is suitable, or the camouflage performance of the simulation pattern in the far-infrared band is suitable.

In an embodiment, the camouflage pattern forming device 100 may verify whether the camouflage performance of each simulation pattern of a plurality of wavelength bands is suitable, using a threshold for camouflage performance, based on artificial intelligence. The camouflage pattern forming device 100 may proceed to operation S170 when the camouflage performance of the simulation pattern in all wavelength bands is suitable.

When the simulation data of any one wavelength band does not have suitable camouflage performance, the camouflage pattern forming device 100 may return to operation S140 and may perform operations S140 to S160. For example, the camouflage pattern forming device 100 may return to operation S130 when the camouflage performance of the simulation data in the visible light band is not suitable, but the camouflage performance of the simulation data in other bands is suitable.

In operation S170, the camouflage pattern forming device 100 may form and display each camouflage pattern for each of a plurality of wavelength bands on the camouflage pattern forming device 100 based on the verified simulation pattern. In an embodiment, the camouflage pattern forming device 100 may form each camouflage pattern for each of a plurality of wavelength bands through the display unit 140. For example, the camouflage pattern forming device 100 may form and display a camouflage pattern in the visible light band, a camouflage pattern in the near-infrared band, and a camouflage pattern in the thermal infrared band.

Unlike conventional devices that form a camouflage pattern only for a single wavelength band, the camouflage pattern forming device 100 according to the present disclosure may form camouflage patterns for a plurality of wavelength bands.

In addition, unlike the conventional stealth function, the camouflage pattern forming device 100 of the present disclosure may form camouflage patterns in multiple wavelength bands by controlling the amount of heat detected by an infrared detection camera, etc., and may form a camouflage pattern that may not be detected even by advanced detection devices.

The camouflage pattern forming device 100 according to the present disclosure may be included in various equipment to perform effective camouflage. For example, the camouflage pattern forming device 100 may be applied to equipment for observing wild animals, thereby performing observation while reducing human intervention. For another example, the camouflage pattern forming device 100 may be widely applied to equipment other than military purposes, such as maximizing the efficiency of crime prevention by being applied to crime prevention equipment.

According to an embodiment of the present disclosure, a camouflage pattern forming device with respect to a plurality of wavelength bands and a method thereof are provided, and a camouflage pattern forming device that is not detected even by improved detection equipment is provided.

The above descriptions are detail embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. Therefore, the scope of the present disclosure should not be limited to the above-described embodiments and should be defined by not only the claims to be described later, but also those equivalent to the claims of the present disclosure.

What is claimed is:

1. A camouflage pattern forming device comprising:
a communication unit configured to receive first data including a location of an observer from an external device;
an information collection unit configured to collect second data including images for each of a plurality of wavelength bands in external environment;
a pattern forming unit configured to form pattern data of the plurality of wavelength bands by performing machine learning based on the first data, the second data, and third data including camouflage pattern data for each environment; and
a display unit configured to receive the pattern data from the pattern forming unit to form and display a camouflage patterns of the plurality of wavelength bands, and
wherein the display unit includes a display device and a heat generator capable of adjusting a heat emissivity.

2. The camouflage pattern forming device of claim 1, wherein the number of the plurality of wavelength bands is determined depending on a surrounding environment of the camouflage pattern forming device and a wavelength band detectable by the observer, and
the surrounding environment includes a time of the forming and displaying the camouflage pattern.

3. The camouflage pattern forming device of claim 1, wherein the first data further includes location information and surrounding environment information of the camouflage pattern forming device, and location information of a detection equipment of the observer.

4. The camouflage pattern forming device of claim 1, wherein the second data is collected by an observation equipment, and
the observation equipment includes a camera, a thermal imaging camera, and a heat detector.

5. The camouflage pattern forming device of claim 1, wherein the pattern forming unit further forms a first simulation pattern by performing the machine learning based on a comparison and analysis of the first data, the second data, and the third data through the machine learning.

6. The camouflage pattern forming device of claim 2, wherein the plurality of wavelength bands include:
a visible light band;
a near-infrared band; and
a thermal infrared band, and
wherein the time for forming the camouflage pattern include day and night,
when it is the day, the camouflage pattern in the visible light band, the near-infrared band, and the thermal infrared band is formed and displayed, and
when it is the night, the camouflage pattern in the near-infrared band, and the thermal infrared band is formed and displayed.

7. The camouflage pattern forming device of claim 5, wherein the pattern forming unit verifies a camouflage performance by comparing the camouflage performance of the first simulation pattern with a threshold, and
determines whether to form the pattern data.

8. The camouflage pattern forming device of claim 7, wherein the pattern forming unit:
when the camouflage performance of the simulation pattern exceeds the threshold, forms the pattern data,
when the camouflage performance of the simulation pattern does not exceed the threshold, forms a second simulation pattern by performing the machine learning based on the comparison and analysis of the first data, the second data, and the third data through the machine learning, and
verifies the camouflage performance of the second simulation pattern.

9. A method of forming a camouflage pattern of a camouflage pattern forming device, the method comprising:
receiving first data including a location of an observer from an external device;
forming a simulation pattern of a plurality of wavelength bands by performing machine learning based on the first data, second data including images of the plurality of wavelength bands of a surrounding environment of the camouflage pattern forming device, and third data including camouflage pattern data for each environment;
verifying a camouflage performance of the simulation pattern; and
forming and displaying the camouflage pattern corresponding to each of the plurality of wavelength bands based on the simulation pattern for which the camouflage performance is verified.

10. The method of claim 9, wherein the number of the plurality of wavelength bands is determined depending on the surrounding environment of the camouflage pattern forming device and a wavelength band detectable by the observer, and
the surrounding environment includes a time of the forming and displaying the camouflage pattern.

11. The method of claim 9, wherein the first data further includes location information and surrounding environment information of the camouflage pattern forming device, and location information of a detection equipment of the observer.

12. The method of claim 9, wherein the second data is collected by an observation equipment, and
the observation equipment includes a camera, a thermal imaging camera, and a heat detector.

13. The method of claim 9, wherein the simulation pattern of the plurality of wavelength bands is formed by comparing and analyzing the first data, the second data, and the third data based on an artificial intelligence.

14. The method of claim 9, wherein the verification of the camouflage performance is performed by comparing the camouflage performance of the simulation pattern with a threshold based on an artificial intelligence.
